(19) United States
(12) Patent Application Publication
(10) Pub. No.: US 2004/0137745 A1
(43) Pub. Date: Jul. 15, 2004

(54) Method and apparatus for removing backside edge polymer

(75) Inventors: Thomas F. Houghton, Marlboro, NY (US); Bradley P. Jones, Pleasant Valley, NY (US); Pavel Smetana, Poughkeepsie, NY (US); Horatio S. Wildman, Wappingers Falls, NY (US)

Correspondence Address: SCHMEISER, OLSEN + WATTS, SUITE 201, 3 LEAR JET, LATHAM, NY, 12033, US

(73) Assignee: International Business Machines Corporation, Armonk, NY

(21) Appl. No.: 10/341,275

(22) Filed: Jan. 10, 2003

(51) Int. Cl. H01L 21/302; H01L 21/461

(52) U.S. Cl. 438/706

(57) ABSTRACT

A method and apparatus for removing a deposited layer on a bottom surface of a substrate, the deposited layer proximate to an edge of the substrate. The method comprises: providing a chuck for supporting the bottom surface of the substrate, an peripheral portion of the bottom surface proximate to the edge extending past a periphery of the chuck; positioning a shield spaced away from and over a top surface of the substrate, a bottom surface of the shield opposite a top surface of the substrate; directing a reactant containing gas to the bottom surface of the substrate proximate to the edge of the substrate; and converting the reactant gas to a reactant species, the reactant species reacting with the deposited layer in order to cause removal of the deposited layer from the substrate.

### FIELD OF THE INVENTION

The present invention relates to the field of semiconductor substrate cleaning; more specifically, it relates to an apparatus for removal of polymer deposits from the backside and edge of semiconductor substrates.

### BACKGROUND OF THE INVENTION

Fluorocarbon based plasma etch processes for dielectric materials used to create damascene wiring patterns produce, to various degrees, an unwanted fluorocarbon polymer layer on the underside of semiconductor substrates proximate to the edge of the substrate. While these unwanted polymers are produced using ordinary interlevel dielectric (ILD) materials such as silicon oxides, it has been found that etching more advanced dielectric materials, for example SILK™ (a polyphenylene oligomer) manufactured by Dow Chemical, Midland, Mich. produces even greater quantities of these polymers.

Subsequently deposited materials, for example silicon oxides, do not adhere well to the fluorocarbon polymer and consequently flake off, contaminating process tools with resultant high maintenance costs and causing defects to the integrated circuit wiring thus degrading yields. Therefore, there is a need in the industry for removal of backside edge polymers.

### SUMMARY OF THE INVENTION

A first aspect of the present invention is an apparatus for removing a deposited layer on a bottom surface of a substrate, the deposited layer proximate to an edge of the substrate comprising: a chuck for supporting the bottom surface of the substrate, a peripheral portion of the bottom surface proximate to the edge extending past a periphery of the chuck; a shield spaced away from and positioned over a top surface of the substrate, a bottom surface of the shield opposite a top surface of the substrate; a supply of a reactant containing gas capable of directing the reactant containing gas to the bottom surface of the substrate proximate to the edge of the substrate; and means for converting the reactant gas to a reactant species, the reactant species capable of reacting with the deposited layer in order to cause removal of the deposited layer from the substrate.

A second aspect of the present invention is a method for removing a deposited layer on a bottom surface of a substrate, the deposited layer proximate to an edge of the substrate comprising: providing a chuck for supporting the bottom surface of the substrate, a peripheral portion of the bottom surface proximate to the edge extending past a periphery of the chuck; positioning a shield spaced away from and over a top surface of the substrate, a bottom surface of the shield opposite a top surface of the substrate; directing a reactant containing gas to the bottom surface of the substrate proximate to the edge of the substrate; and converting the reactant gas to a reactant species, the reactant species reacting with the deposited layer in order to cause removal of the deposited layer from the substrate.

### BRIEF DESCRIPTION OF DRAWINGS

The features of the invention are set forth in the appended claims. The invention itself, however, will be best understood by reference to the following detailed description of an illustrative embodiment when read in conjunction with the accompanying drawings, wherein:

FIG. 1 is partial cross-section view of a semiconductor substrate illustrating the location of a layer of polymer that is removed by the present invention;

FIG. 2 is schematic diagram of an apparatus for removal of a backside edge polymer according to a first embodiment of the present invention;

FIG. 3 is a detailed view of the apparatus of FIG. 2 near the edge of the substrate;

FIG. 4 is a detailed view of an alternative configuration of the apparatus of FIG. 2 near the edge of the substrate;

FIG. 5 is schematic diagram of an apparatus for removal of a backside edge polymer according to a second embodiment of the present invention;

FIG. 6 is a detailed view of the apparatus of FIG. 5 near the edge of the substrate FIG. 7 is schematic diagram of an apparatus for removal of a backside edge polymer according to a third embodiment of the present invention; and

FIG. 8 is a detailed view of the apparatus of FIG. 7 near the edge of the substrate.

### DETAILED DESCRIPTION OF THE INVENTION

In the context of the present invention, the term wafer should be understood to include a variety of semiconductor substrates, such as bulk silicon substrates, silicon on insulator substrates, quartz substrates and sapphire substrates.

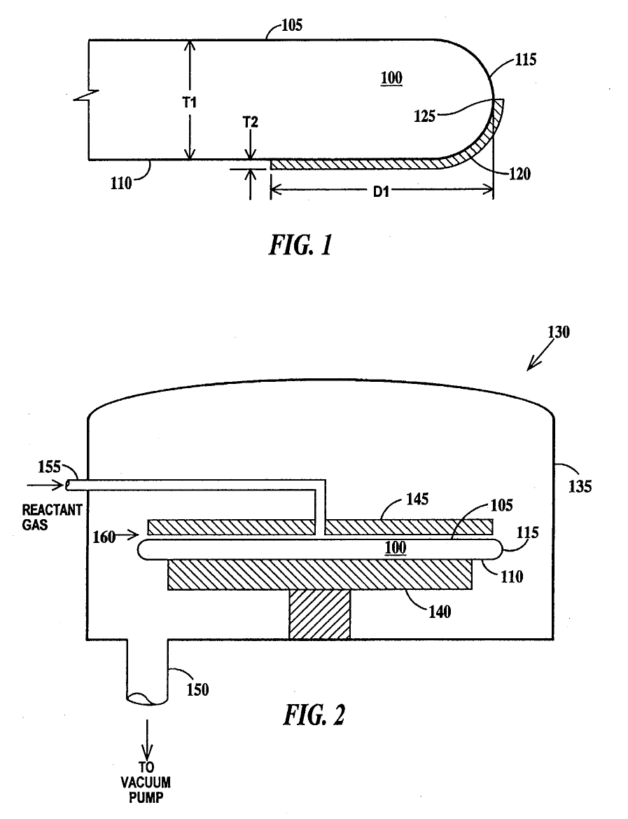

FIG. 1 is partial cross-section view of a semiconductor substrate illustrating the location of a layer of polymer that is removed by the present invention. In FIG. 1, wafer 100 has a top surface 105, a bottom surface 110 and an edge 115. Wafer 100 has a thickness of “T1.” In the case of a 200 mm diameter bulk silicon substrate, “T1” may be about 750 microns. Because edge 115 of wafer 100 is beveled, the lower portion of the bevel is “shadowed” from the etchant species, which are generally directed normal to top surface 105 and which would otherwise remove any polymeric deposits. Thus a polymer layer 120 is deposited on any portion of bottom surface 110 exposed to the etch chamber environment and on a contiguous lower portion of edge 115. Polymer layer 120 extends a distance “D1” along bottom surface 110 from edge 115. “D1” is determined by the distance wafer 100 extended past the edge of the wafer chuck of the plasma etch tool that formed polymer layer 120. Typically, “D1” is about 2 mm. Polymer layer 120 extends from bottom surface 110 to about midpoint 125 of edge 115. In a typical dielectric plasma etch process, Polymer layer 120 is a fluorocarbon polymer whose thickness “T2” may be about 0.1 micron or greater.

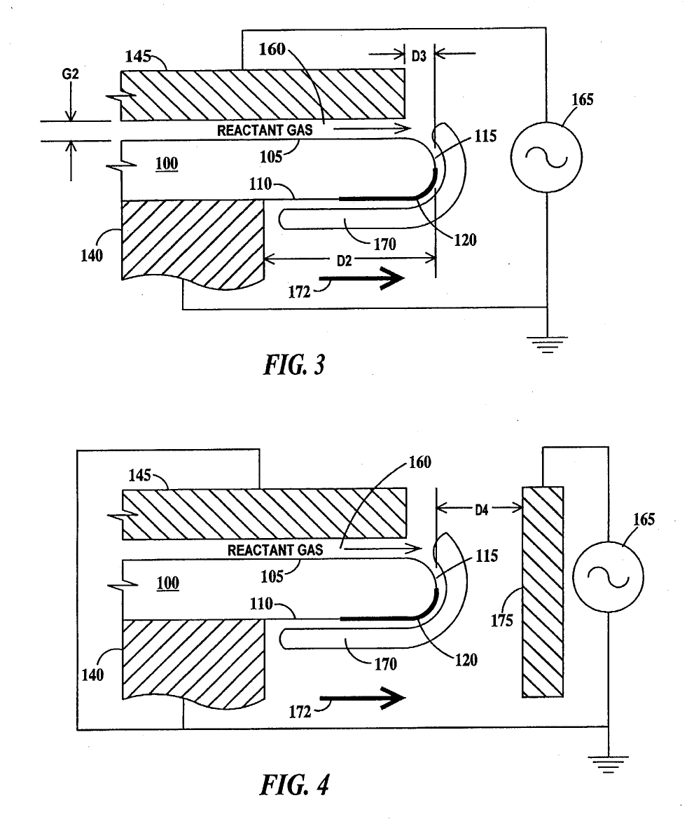

FIG. 2 is schematic diagram of an apparatus for removal of a backside edge polymer according to a first embodiment of the present invention. In FIG. 2, a plasma ash apparatus 130 includes a chamber 135, a wafer chuck 140 and a shield 145 centered above the wafer chuck. Shield 140 and wafer chuck 145 are electrically conductive. In one example, shield 140 and wafer chuck 145 are formed from anodized aluminum. Wafer 100 is approximately centered on and held to wafer chuck 140 by electrostatic or other means. Top surface 105 of wafer 100 faces shield 145. A portion of bottom surface 110 (proximate to edge 115) of wafer 100 overhangs wafer chuck 140. Chamber 135 includes an exhaust 150 that is connected to a high vacuum pump (not shown) for producing a relatively high vacuum in the chamber and a reactant gas supply tube 155. Reactant gas supply tube 155 supplies a reactant gas or gas mixture through shield 145 for distribution throughout a gap 160 between shield 145 and top surface 105 of wafer 100. Plasma ash apparatus 130 also includes an RF source as illustrated in FIGS. 3 and 4 and described infra.

FIG. 3 is a detailed view of the apparatus of FIG. 2 near the edge of the wafer 100. In FIG. 3, an RF source 165 is coupled between shield 145 and ground. Wafer chuck 140 (as well as wafer 100) is coupled to ground. RF source 165 generates a plasma discharge region 170 proximate to bottom surface 110 and edge 115 of wafer 100. Plasma discharge region 170 forms around the bottom surface 110 and edge 115 of wafer 100. Plasma discharge region 170 generates, from the reactant gases, oxidizing species such as oxygen ions or oxygen free radicals that react with polymer layer 120 forming a volatile reaction product and thus removing the polymer layer. Shield 145 is spaced a distance “G1” from top surface 105 of wafer 100 forming a gap 160. The value of “G1” is chosen to be too small to support a discharge region between shield 145 and top surface 105 of wafer 100. Thus, no reactant species that could etch structures or materials formed on top surface 105 of wafer 100 are generated over the top surface and the top surface is protected by shield 145. Bottom surface 110 of wafer 100 extends a distance “D2” beyond wafer chuck 140 in the direction 172. Top surface 105 of wafer 100 extends a distance “D3” beyond shield 145 in the direction 172.

In one example, “G1” is about 0.5 to 1 mm, “D2” is about 3 to 5 mm, “D3” is about 0.5 to 1 mm and the reactant gas comprises oxygen, an oxygen/tetraflouromethane mixture, an oxygen/fluorine mixture, oxygen diluted with argon or nitrogen, an oxygen/tetraflouromethane mixture diluted with argon or nitrogen or an oxygen/fluorine mixture diluted with argon or nitrogen.

An exemplary backside edge ash process for the apparatus illustrated in FIGS. 2 and 3 may be run at a pressure of about 2 to 2 torr, an oxygen flow rate of about 1000 to 3000 sccm sccm/sec and about 500 to 1500 watts forward bias for about 30 to 60 seconds seconds.

FIG. 4 is a detailed view of an alternative configuration of the apparatus of FIG. 2 near the edge of the substrate. FIG. 4 is identical to FIG. 3 except that an auxiliary ring electrode 175 has been added. Ring electrode 175 is electrically conductive. In one example, ring electrode 175 is formed from anodized aluminum. Ring electrode 175 is coupled to RF source 165. Shield 145 and chuck 140 are coupled to ground. Ring electrode 175 is positioned a distance “D4” beyond edge 115 of wafer 100 in direction 172. In one example, “D4” is about 10 to 15 mm. Reactant gases are the same as those discussed supra in reference to FIG. 3.

An exemplary backside edge ash process for the apparatus illustrated in FIGS. 2 and 4 may run at a pressure of about 2 to 3 torr, an oxygen flow rate of about 1000 to 3000 sccm/sec and about 500 to 1500 watts forward bias for about 30 to 60 seconds.

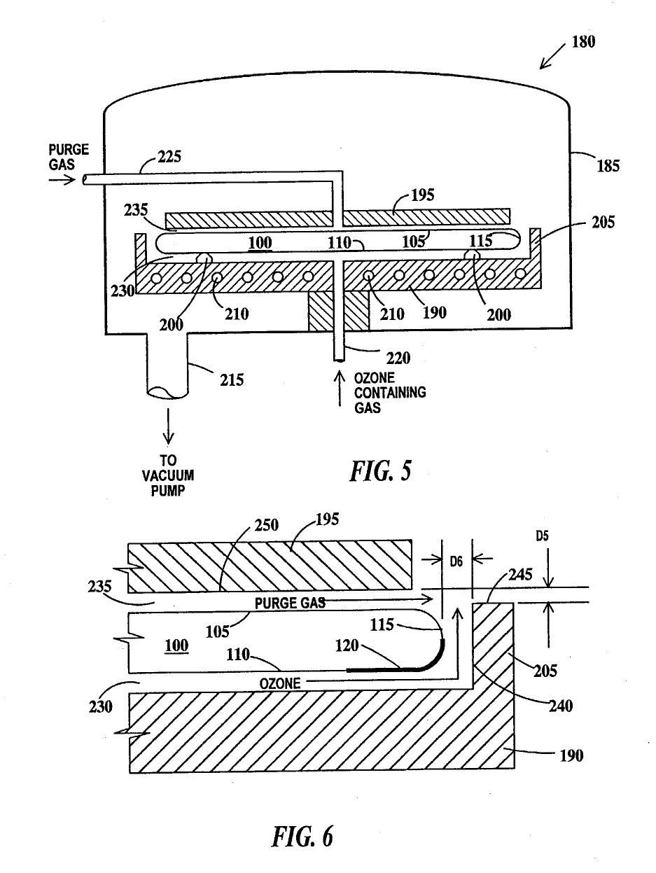

FIG. 5 is schematic diagram of an apparatus for removal of a backside edge polymer according to a second embodiment of the present invention. In FIG. 3, an ozone clean apparatus 180 includes a chamber 185, a wafer chuck 190 and a shield 195 centered above the wafer chuck. Wafer 100 is approximately centered on and suspended above wafer chuck 190 by lift pins 200. Top surface 105 of wafer 100 faces shield 195. A lip 205 of wafer chuck 190 surrounds edge 115 of wafer 100. Wafer chuck 195 includes optional channels 210 that may contain electrical heating coils or through which a hot fluid may be circulated in order to heat the wafer chuck. Electrical heating is preferred. Chamber 185 includes an exhaust 215 that is connected to a vacuum pump (not shown) for producing a medium to high vacuum in the chamber, a reactant gas supply tube 220 and a purge gas supply tube 225. Reactant gas supply tube 220 supplies ozone or an ozone mixture (generated by an ozone generator, not shown) through wafer chuck 190 for distribution throughout a gap 230 between wafer chuck 190 and bottom surface 110 of wafer 100. Purge gas supply tube 225 supplies an inert gas or gas mixture through shield 195 for distribution throughout a gap 235 between shield 195 and top surface 105 of wafer 100.

FIG. 6 is a detailed view of the apparatus of FIG. 5 near the edge of the wafer 100. In FIG. 6, edge 115 of wafer 100 is posited a distance “D5” from an inside surface 240 of lip 205 of wafer chuck 190. Ozone flowing past bottom surface 110 and edge 115 of wafer 100 reacts with polymer layer 120 forming a volatile reaction product and thus removing the polymer layer. A top edge 245 of lip 205 is positioned a distance “D6” below a plane defined by a lower surface 250 of shield 195. Distance “D6” is selected to reduce back diffusion of ozone onto top surface 105 of wafer 100. The purge gas also helps to keep ozone away from top surface 105 of wafer 100.

In one example, “D5” is about 1 to 2 mm, “D6” is about 1 to 2 mm, the reactant gas is ozone, an ozone/argon mixture, an ozone/nitrogen mixture or an ozone/oxygen mixture and the purge gas is nitrogen or argon and the wafer chuck is heated to between about room temperature (i.e. 20° C.) and 300° C. Heating will increase the reaction rate and hence the removal rate of polymer layer 120.

An exemplary backside edge ozone clean process for the apparatus illustrated in FIGS. 5 and 6 may be run at a pressure of about 100 to 200 torr and an ozone flow rate of about 3000 to 5000 sccm/sec at temperature of about 200 to 300° C. for about 60 to 120 seconds.

FIG. 7 is schematic diagram of an apparatus for removal of a backside edge polymer according to a third embodiment of the present invention. In FIG. 2, a plasma torch clean apparatus 260 includes a chamber 265, a rotatable wafer chuck 270 and a shield 275 centered above the wafer chuck. Wafer chuck 270 is rotated by rotating shaft 280. Wafer 100 is approximately centered on and held to wafer chuck 270 by electrostatic or other means. Top surface 105 of wafer 100 faces shield 275. A portion of bottom surface 110 (proximate to edge 115) of wafer 100 overhangs wafer chuck 270. Chamber 265 includes an exhaust 285 that is connected to an exhaust fan (not shown) for removing waste gas process gas and reaction products. Apparatus 260 is run at essentially room pressure. A purge gas supply tube 290 supplies an inert gas or gas mixture through shield 275 for distribution throughout a gap 295 between shield 275 and top surface 105 of wafer 100. A reactant gas supply tube 300 supplies a reactant gas or gas mixture to a plasma torch 305. Plasma torch 305 produces a plasma region 310 that contacts an exposed portion of bottom surface 110 and a contiguous portion of edge 115 of wafer 310. Use of shield 275 and purge gas 295 ensures that plasma region 310 does not damage any structures formed on top surface 105 of wafer 100 or that any reaction products formed by removal of polymer layer 120 do not re-deposit on top surface 105.

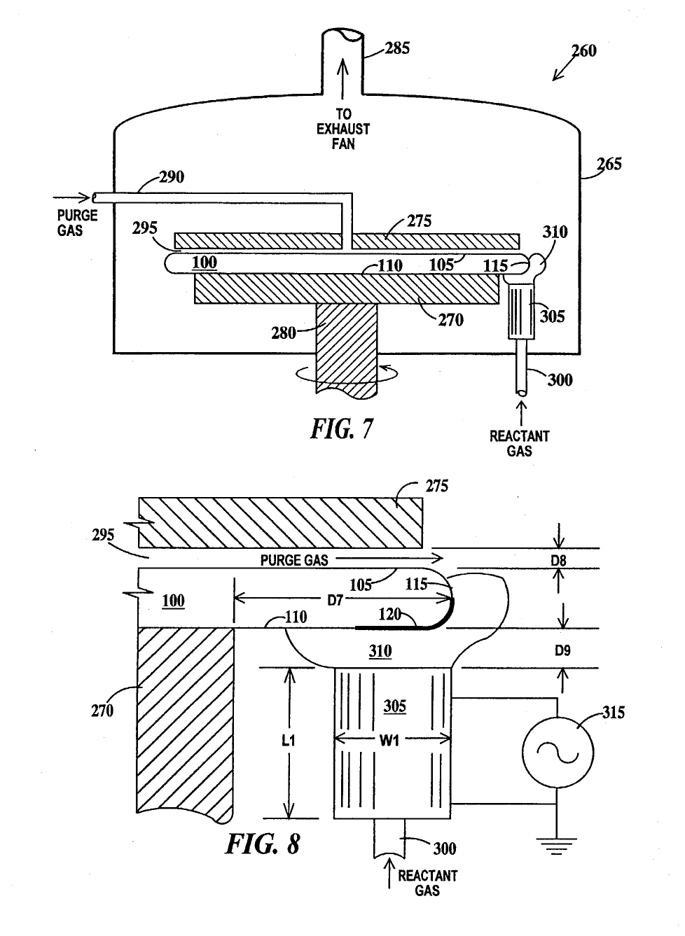

FIG. 8 is a detailed view of the apparatus of FIG. 7 near the edge of the substrate. In FIG. 8, wafer 100 extends a distance “D7” from wafer chuck 270. If optional shield 275 is used, the shield is spaced a distance “D8” from top surface 105 of wafer 100. Plasma torch 305 includes a RF source 315. RF source 315 generates plasma region 310 that contacts bottom surface 110 and edge 115 of wafer 100. Plasma torch 305 is positioned a distance “D9” from bottom surface 110 of wafer 100. Plasma region 310 includes oxidizing species such as oxygen ions or oxygen free radicals that react with polymer layer 120 forming a volatile reaction product and thus removing the polymer layer as wafer 100 is rotated past plasma torch 305.

There are two types of plasma torches available, an inductively coupled device and a capacitively coupled device. An example of an inductively coupled is a RAP (reactive atom plasma) device manufactured by RAPT Inc. of Livermore, Calif. and is described in United State Patent Publication 2002/0100751A1, which is hereby incorporated by reference. An example of a capacitively coupled device is manufactured by Apjet Inc. of Los Alamos, N. Mex.

Plasma torch 305 has a length “L1” and a diameter of “W1.” In one example “L1 is about 3 inches and “W1” is about 1 inch.

In one example, “D7” is about 50 mm, “D8” is about 1 to 2 mm, “D9” is about 1 to 5 mm, the reactant gas is oxygen, an oxygen/tetraflouromethane mixture, an oxygen/fluorine mixture, oxygen diluted with argon or nitrogen, an oxygen/tetraflouromethane mixture diluted with argon or nitrogen or an oxygen/fluorine mixture diluted with argon or nitrogen and the purge gas is nitrogen or argon. It is possible for the reactant gas and the purge gas to be the same.

An exemplary backside edge plasma torch clean process for the apparatus illustrated in FIGS. 7 and 8 may be run at an oxygen flow rate of about 500 to 1000 sccm and about 500 to 1000 watts forward bias (torch) for about 30 to 60 seconds while the wafer is rotated at about 5 to 10 RPM.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. For example, the wafer chuck may be heated in the first and third embodiments of the present invention as well as the first embodiment as illustrated in FIG. 5 and described supra. Therefore it is intended that the following claims cover all such modifications and changes as fall within the true spirit and scope of the invention.

What is claimed is:

1. An apparatus for removing a deposited layer on a bottom surface of a substrate, said deposited layer proximate to an edge of said substrate comprising:
a chuck for supporting said bottom surface of said substrate, a peripheral portion of said bottom surface proximate to said edge extending past a periphery of said chuck;
a shield spaced away from and positioned over a top surface of said substrate, a bottom surface of said shield opposite a top surface of said substrate;
a supply of a reactant containing gas capable of directing said reactant containing gas to said bottom surface of said substrate proximate to said edge of said substrate; and
means for converting said reactant gas to a reactant species, said reactant species capable of reacting with said deposited layer in order to cause removal of said deposited layer from said substrate.

2. The apparatus of claim 1, further including a supply of a purge gas capable of directing said purge gas between said top surface of said substrate and said bottom surface of said shield.

3. The apparatus of claim 1, further including means for heating said chuck.

4. The apparatus of claim 2, wherein said means for converting said reactant gas to said reactant species comprises an ozone generator.

5. The apparatus of claim 2, wherein said means for converting said reactant gas to said reactant species comprises a plasma torch.

6. The apparatus of claim 5, wherein said reactant gas is selected from the group consisting of oxygen, an oxygen/tetraflouromethane mixture, an oxygen/fluorine mixture, oxygen diluted with argon or nitrogen, an oxygen/tetraflouromethane mixture diluted with argon or nitrogen and an oxygen/fluorine mixture diluted with argon or nitrogen.

7. The apparatus of claim 1, further including means for rotating said chuck.

8. The apparatus of claim 1, further including means for directing said reactant gas between said top surface of said substrate and said bottom surface of said shield before said reactant gas is directed to said bottom surface of said substrate proximate to said edge of said substrate.

9. The apparatus of claim 8, wherein said means for converting said reactant gas to said reactant species comprises plasma generation means.

10. The apparatus of claim 9, wherein said reactant gas is selected from the group consisting of oxygen, an oxygen/tetraflouromethane mixture, an oxygen/fluorine mixture, oxygen diluted with argon or nitrogen, an oxygen/tetraflouromethane mixture diluted with argon or nitrogen and an oxygen/fluorine mixture diluted with argon or nitrogen.

11. A method for removing a deposited layer on a bottom surface of a substrate, said deposited layer proximate to an edge of said substrate comprising:
providing a chuck for supporting said bottom surface of said substrate, a peripheral portion of said bottom surface proximate to said edge extending past a periphery of said chuck;
positioning a shield spaced away from and over a top surface of said substrate, a bottom surface of said shield opposite a top surface of said substrate;
directing a reactant containing gas to said bottom surface of said substrate proximate to said edge of said substrate; and
converting said reactant gas to a reactant species, said reactant species reacting with said deposited layer in order to cause removal of said deposited layer from said substrate.

12. The method of claim 10, further including directing a purge gas between said top surface of said substrate and said bottom surface of said shield.

13. The method of claim 10, further including heating said chuck.

14. The method of claim 12, wherein said reactant gas is converted to said reactant species in an ozone generator.

15. The method of claim 12, wherein said reactant gas is converted to said reactant species in a plasma torch.

16. The method of claim 15, wherein said reactant gas is selected from the group consisting of oxygen, an oxygen/tetraflouromethane mixture, an oxygen/fluorine mixture, oxygen diluted with argon or nitrogen, an oxygen/tetraflouromethane mixture diluted with argon or nitrogen and an oxygen/fluorine mixture diluted with argon or nitrogen.

17. The method of claim 11, further including rotating said chuck.

18. The method of claim 11, further including directing said reactant gas between said top surface of said substrate and said bottom surface of said shield before said reactant gas is directed to said bottom surface of said substrate proximate to said edge of said substrate.

19. The method of claim 18, wherein said reactant gas is converted to a reactant species by plasma generation means.

20. The method of claim 19, wherein said reactant gas is selected from the group consisting of oxygen, an oxygen/tetraflouromethane mixture, an oxygen/fluorine mixture, oxygen diluted with argon or nitrogen, an oxygen/tetraflouromethane mixture diluted with argon or nitrogen and an oxygen/fluorine mixture diluted with argon or nitrogen.
